(19) United States
(12) Patent Application Publication
(10) Pub. No.: US 2024/0113149 A1
(43) Pub. Date: Apr. 4, 2024

(54) BACKSIDE ILLUMINATED IMAGE SENSOR AND MANUFACTURING METHOD THEREOF

(71) Applicant: DB HiTek Co., Ltd., Bucheon-si (KR)

(72) Inventors: Chang Hun HAN, Icheon-si (KR); Ju Hwan JUNG, Seoul (KR); Sang Won YUN, Daegu (KR); Tae Wook KANG, Yongin-si (KR)

(21) Appl. No.: 18/190,238

(22) Filed: Mar. 27, 2023

(30) Foreign Application Priority Data
Oct. 4, 2022 (KR) 10-2022-0125968

(51) Int. Cl. H01L 27/146

(52) U.S. Cl. CPC H01L 27/1464; H01L 27/14621; H01L 27/14627; H01L 27/14636; H01L 27/14685

(57) ABSTRACT

Disclosed are a backside illuminated image sensor and a method of manufacturing the same. More particularly, a backside illuminated image sensor and a method of manufacturing the backside illuminated image sensor include a plurality of sequential layers have different refractive indexes to extend a path of incident light passing through a lens, thereby increasing sensitivity.

### CROSS REFERENCE TO RELATED APPLICATION

The present application claims priority to Korean Patent Application No. 10-2022-0125968, filed Oct. 4, 2022, the entire contents of which are incorporated herein for all purposes by this reference.

### BACKGROUND OF THE INVENTION

### Field of the Invention

The present disclosure relates to a backside illuminated image sensor and a method of manufacturing the same. More particularly, the present disclosure relates to a backside illuminated image sensor and a method of manufacturing the backside illuminated image sensor including a plurality of sequential layers have different refractive indexes to extend a path of incident light passing through a corresponding lens, thereby increasing sensitivity.

### Description of the Related Art

An image sensor is a component of an imaging device that generates an image in a cell phone 20 camera or the like. According to its manufacturing process and/or application, the image sensor may be classified as a Charge Coupled Device (CCD) image sensor or a Complementary Metal Oxide Semiconductor (CMOS) image sensor. The CMOS image sensor is widely used, as general CMOS semiconductor chip manufacturing processes having a high degree of integration, economic feasibility, and ease of connection with surrounding chips can make CMOS image sensors.

A conventional CMOS image sensor includes a metal wiring, a color filter, and a lens in sequence on a front surface of a silicon wafer. However, in the image sensor having such a structure, the amount of incident light received by a light receiving element may be reduced due to the metal wiring. Accordingly, a backside illuminated CMOS image sensor (BIS) is being developed, including the wiring on the front surface of the substrate, and the color filter and the lens on the back surface of the substrate. Such a BIS is used in an iris scanner, a Time-Of-Flight (Tof) sensor, and so on, and the importance of increasing light sensitivity in a near infrared range is emerging. However, the light sensitivity of a conventional image sensor in the near infrared range is generally not sufficient for the application field(s) described above.

Accordingly, the present inventor has conceived a new backside illuminated image sensor having an improved structure capable of increasing light sensitivity in the near infrared range, and the detailed description thereof will be described below.

### DOCUMENT OF RELATED ART

Korean Patent No. 10-0660549, entitled “IMAGE SENSOR AND METHOD OF MANUFACTURING THE SAME.”

### SUMMARY OF THE INVENTION

Accordingly, the present disclosure has been made keeping in mind the above problems occurring in the related art, and an objective of the present disclosure is to provide a backside illuminated image sensor and a method of manufacturing the backside illuminated image sensor including first to fourth sequential layers having different refractive indexes, to extend a path of incident light passing through a corresponding lens and thereby increase light sensitivity.

Specifically, another objective of the present disclosure is to provide a backside illuminated image sensor and a method of manufacturing the backside illuminated image sensor including a first layer with a first refractive index, a second layer with a second refractive index smaller than the first refractive index, and a third layer with a third refractive index smaller than the first refractive index, thereby extending a path of incident light.

In addition, still another objective of the present disclosure is to provide a backside illuminated image sensor and a method of manufacturing the backside illuminated image sensor including a deep trench isolation (DTI) structure and a refractive index adjustment region that are formed substantially simultaneously in the same process, thereby increasing process efficiency.

The present disclosure may be implemented by one or more embodiments having some or all of the following configurations, to achieve one or more of the above-described objectives.

According to one or more embodiments of the present disclosure, there is provided a backside illuminated image sensor including a substrate having a front surface and a back surface; a light receiving element in the substrate; a plurality of deep trench isolation (DTI) structures at boundaries between a plurality of unit pixels, the DTI structures having a first depth; and a refractive index adjustment region having a second depth less than the first depth and being between adjacent DTI structures in the substrate, wherein each of the DTI structures includes a first boundary region at a boundary of the DTI structure and comprising a first material; and a first center structure on the first boundary region and comprising a second material different from the first material, and the refractive index adjustment region includes a second boundary region at a boundary of the refractive index adjustment region and comprising a third material; and a second center structure on the second boundary region and comprising a fourth material different from the third material.

In the present disclosure, the first boundary region may comprise the same material as the second boundary region, and the first center structure may comprise the same material as the second center structure.

In the present disclosure the backside illuminated image sensor may further include a first connection region connecting each of the DTI structures and the refractive index adjustment region (which may be adjacent to each other on the back surface of the substrate) and/or connecting the adjacent DTI structures to each other; and a second connection region on the first connection region, the second connection region connecting the first center structure and the second center structure to each other.

In the present disclosure, the first connection region may comprise the same material as the first boundary region, and the second connection region may comprise the same material as the first center structure.

In the present disclosure, the substrate may have a first refractive index, the first connection region may have a second refractive index smaller than the first refractive index, and the second connection region may have a third refractive index larger than the second refractive index.

In the present disclosure, the backside illuminated image sensor may further include a first interlayer insulation film on the second connection region, wherein the first interlayer insulation film may have a fourth refractive index smaller than the second refractive index.

According to another embodiment of the present disclosure, there is provided a backside illuminated image sensor including a substrate having a front surface and a back surface; a light receiving element in the substrate; a plurality of DTI structures at boundaries between a plurality of unit pixels; a refractive index adjustment region between adjacent DTI structures in the substrate; a second connection region; and a first interlayer insulation film on the second connection region, wherein each of the DTI structures includes a first boundary region at a boundary of the DTI structure and comprising a first material; and a first center structure on the first boundary region and comprising a second material different from the first material, and the refractive index adjustment region includes a second boundary region at a boundary of the refractive index adjustment region and comprising a third material; and a second center structure on the second boundary region and comprising a fourth material different from the third material.

In the present disclosure, the backside illuminated image sensor may further include a first connection region connecting each of the DTI structures and the refractive index adjustment region (which may be adjacent to each other on the back surface of the substrate); a second connection region connecting the first center structure and the second center structure (e.g., on the first connection region); a first layer in the substrate, having a first refractive index and including the first boundary region and the second boundary region; a second layer on the first layer, having a second refractive index and including the first connection region; a third layer on the second layer, having a third refractive index and including the second connection region; and a fourth layer on the third layer, having a fourth refractive index and including the first interlayer insulation film, wherein the first refractive index larger than the third refractive index, and the second refractive index is smaller than the first and third refractive indexes and larger than the fourth refractive index.

In the present disclosure, the refractive index adjustment region may have a depth shallower than a depth of each of the DTI structures in the substrate.

In the present disclosure, the backside illuminated image sensor may further include a second interlayer insulation film on the first interlayer insulation film; a light shield at the boundary of each of the unit pixel regions and in the second interlayer insulation film; a color filter on the second interlayer insulation film; and a lens on the color filter.

In the present disclosure, the refractive index adjustment region may include a plurality of refractive index adjustment regions, and the plurality of refractive index adjustment regions may be spaced apart from each other between adjacent ones of the DTI structures in each of the unit pixel regions.

In the present disclosure, the first boundary region may be formed substantially simultaneously with the second boundary region and the first connection region (e.g., in the same process[es]), and the first center structure may be formed substantially simultaneously with the second center portion and the second connection region (e.g., in the same process[es]).

In the present disclosure, the first boundary region may include a first insulating material having a fifth refractive index, the first center structure may include a second insulating material having a sixth refractive index, and the fifth refractive index may be smaller than the sixth refractive index.

According to still another embodiment of the present disclosure, there is provided a backside illuminated image sensor including a substrate having a front surface and a back surface; a first layer having a first refractive index and including a plurality of trench structures in the substrate (e.g., which extend in a front surface direction from the back surface of the substrate), spaced apart from each other; a second layer having a second refractive index and including a plurality of connection structures on the first layer, connecting adjacent trench structures; a third layer having a third refractive index, on the second layer and covering the trench structures and connection structures; and a fourth layer having a fourth refractive index and comprising an interlayer insulation film structure on the third layer, wherein the first refractive index is larger than the third refractive index, and the second refractive index is smaller than the first and third refractive indexes and larger than the fourth refractive index.

In the present disclosure the backside illuminated image sensor may further include an insulation film on the fourth layer; and a light shield comprising a metal film, at a boundary of a unit pixel and in the insulation film.

In the present disclosure, the backside illuminated image sensor may further include a color filter on the insulation film; a planarization layer on the color filter; and a lens on the planarization layer.

In the present disclosure, the backside illuminated image sensor may further include a wiring region on the front surface of the substrate.

According to an embodiment of the present disclosure, there is provided a method of manufacturing a backside illuminated image sensor, the method including forming a wiring region on a front surface of a substrate; forming first trenches (which may extend in a front surface direction) in a back surface of the substrate; forming a second trench between the first trenches, the second trench having a depth less than that of the first trenches; forming a first insulating material having a first refractive index in the first trenches, in the second trench, and on the back surface of the substrate; forming a second insulating material on the first insulating material, the second insulating material having a second refractive index larger than the first refractive index and smaller than a third refractive index of the substrate; and forming an interlayer insulation film on the second insulating material, the interlayer insulation film having a fourth refractive index smaller than the first refractive index.

In the present disclosure, the second trench may include a plurality of second trenches, and the plurality of second trenches may be formed between adjacent ones of the first trenches.

According to the above configurations, the present disclosure has the following effects.

In the present disclosure, since refractive indexes of the first layer to the fourth layer differ, the path of incident light from the lens may be extended, increasing the light sensitivity.

Specifically, since the second layer has a smaller refractive index than the first layer (which may have the largest refractive index) and the third layer, the path of incident light (e.g., through the first through third layers and/or the backside illuminated image sensor) may be extended.

In addition, since the DTI structures and the refractive index adjustment region may be formed in substantially and simultaneously the same process(es), process efficiency may increase.

Meanwhile, though not explicitly mentioned, effects described in the present specification and tentative effects, expected from the technical features of the present specification will be treated as if described in the present specification.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a backside illuminated image sensor according to an embodiment of the present disclosure;

FIGS. 2A and 2B are reference views comparing light paths in the backside illuminated image sensor of FIG. 1; and

FIGS. 3 to 8 are cross-sectional views illustrating structures made during a method of manufacturing the backside illuminated image sensor according to one or more embodiments of the present disclosure.

### DETAILED DESCRIPTION OF THE INVENTION

Hereinafter, embodiments of the present disclosure will be described in detail with reference to accompanying drawings. Various changes to the following embodiments are possible and the scope of the present disclosure is not limited to the following embodiments. The patent right of the present disclosure should be defined by the scope and spirit of the present disclosure as recited in the accompanying claims. In addition, embodiments of the present disclosure are intended to fully describe the present disclosure to a person having knowledge in the art to which the present disclosure pertains.

As used in this specification, a singular form may include a plural form unless extended definitely indicates a particular form. Also, the expressions “comprise” and/or “comprising” as used in this specification neither define the mentioned shapes, numbers, steps, operations, members, elements, and/or groups of these, nor exclude the presence or addition of one or more other different shapes, numbers, steps, operations, members, elements, and/or groups of these, or additions to these.

Hereinafter, when it is described that a component (or a layer) is referred to as being on another component (or another layer), it should be understood that the component may be directly on the other component, or one or more intervening components (or layers) may also be present. In contrast, when it is described that a component is referred to as being directly on to another component, it should be understood that there is (are) no intervening component(s) present. In addition, the terms indicating positions, such as, being located ‘on’, ‘upper’, ‘lower’, ‘upper side’, ‘lower side’, ‘first side’, and ‘side surface’ are intended to mean a relative position of the components.

Meanwhile, when an embodiment can be implemented differently, steps or operations described in the present specification may be performed in a different way from those described. For example, two consecutive functions or operations may be performed simultaneously, or in reverse order.

Hereinafter, for example, a first-conductivity-type impurity region may refer to a ‘P-type’ doped region, and a second-conductivity-type impurity region may refer to an ‘N-type’ doped region. Otherwise, in some cases, a first-conductivity-type impurity region may refer to an ‘N-type’ doped region and a second-conductivity-type impurity region may refer to a ‘P-type’ doped region, and there is no limitation.

A backside illuminated image sensor 1 according to the present disclosure includes a pixel P. The pixel P absorbs light incident toward a back surface of a substrate 101 from the outside. The backside illuminated image sensor 1 may include a plurality of unit pixels P1.

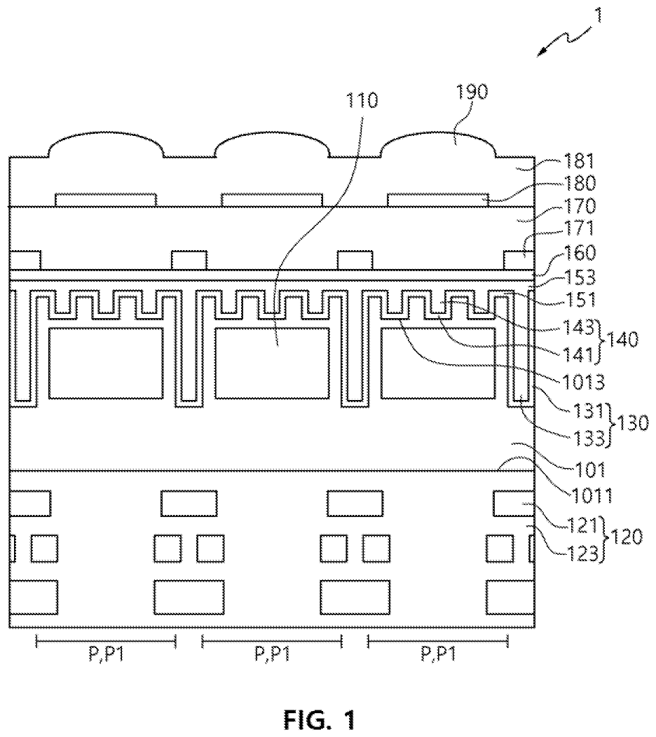

FIG. 1 is a cross-sectional view illustrating a backside illuminated image sensor according to an embodiment of the present disclosure.

Hereinafter, a backside illuminated image sensor 1 according to an embodiment of the present disclosure will be described in detail with reference to the accompanying drawings.

Referring to FIG. 1, the present disclosure relates to the backside illuminated image sensor 1. More particularly, the present disclosure relates to the backside illuminated image sensor 1 including a plurality of sequential layers having different refractive indexes to extend a path of incident light passing through or from a corresponding lens, thereby increasing sensitivity (e.g., of the image sensor 1) in a near infrared band of light.

For example, the substrate 101 may comprise a single-crystal substrate with an epitaxial layer thereon (e.g., an epitaxial silicon layer on a monolithic silicon wafer), a bulk substrate, or the like. In addition, the substrate 101 has a front surface 1011 and a back surface 1013. A wiring region 120 that will be described later is on the front surface 1011, and light is incident from the back surface 1013. The pixel P of the substrate 101 may further include at least one light receiving element 110 (e.g., a photodiode) and at least one transistor (not illustrated) electrically connected to the light receiving element 110.

The light receiving element 110 is configured to generate a charge in response to absorption of incident light. For example, the light receiving element 110 may comprise any known configuration or known device such as a photodiode, a photo gate, a photo transistor, and so on, and there is no specific limitation. In addition, each of the unit pixels P1 includes a light receiving element 110.

As described above, the wiring region 120 is on the front surface 1011 of the substrate 101, and the wiring region 120 may include a metal wiring layer 121 and a lower insulation film 123.

For example, the metal wiring layer 121 may comprise a single (elemental) metal or an alloy film including at least two types of metals, and may preferably comprise an aluminum (Al) or aluminum alloy film. In addition, in the lower insulation film 123, the metal wiring layer 121 may alternate in a multilayered structure.

For example, the lower insulation film 123 comprises an insulating material such as silicon dioxide, and may repeatedly alternate with the metal wiring layer 121, and it is preferable that the metal wiring layer 121 comprises a multilayer wiring. Any one metal wiring layer 121 may be connected to another metal wiring layer 121 through a contact or plug (not illustrated). Using a damascene process, the contact or plug may be formed in the lower insulation film 123. Furthermore, the contact or plug may comprise a conductive material selected from, for instance, polycrystalline silicon doped with an impurity ion, a metal, or an alloy including at least two types of metals, such that the metal wiring layers 121 above and below the contact or plug are electrically connected with each other.

The lower insulation film 123 may comprise one or more oxide films selected from a borophosphosilicate glass (BPSG), a phosphosilicate glass (PSG), a borosilicate glass (BSG), an undoped silicate glass (USG), a silicon dioxide film formed from tetraethyl orthosilicate (TEOS), a silicon dioxide film formed using a high-density plasma (HDP), or a multi-layer film including at least two of the oxide films described above. In addition, after deposition, the lower insulation film 123 may be planarized by chemical mechanical polishing (CMP), for example.

In addition, deep trench isolation (DTI) structures 130 may be at the boundaries between adjacent unit pixels P1 in the substrate 101. The DTI structures 130 may extend to a predetermined depth in the substrate 101 (e.g., toward the front surface 1011 from the back surface 1013 of the substrate 101). In addition, for example, the DTI structures 130 may comprise one or more of the oxide films selected from the BPSG film, the PSG film, the BSG film, the USG film, the TEOS film, and the HDP film, but there is no limitation. In addition, the DTI structures 130 may have a square or rectangular shape in a plan view, and may appear as a mesh structure, for example. The DTI structures 130 may include a first boundary region 131 and a first center structure 133.

The first boundary region 131 may comprise an insulation film configuration along a boundary of the DTI structures 130, and may be connected to a second boundary region 141 that will be described later. It is preferable that the first boundary region 131 and the second boundary region 141 comprise the same material. In addition, the first boundary region 131 may have substantially the same thickness along the boundary of the DTI structures 130, but there is no specific limitation. The first boundary region 131 may be connected to the second boundary region 141 by a first connection region 151.

The first center structure 133 is a part of the DTI structures 130, together with the first boundary region 131, and may fill the first boundary region 131. In addition, the first center structure 133 may be connected to a second center structure 143 by a second connection region 153.

In describing the present disclosure again, at least one refractive index adjustment region 140 may be between adjacent DTI structures 130. That is, at least one refractive index adjustment region 140 may be in the unit pixel P1. The refractive index adjustment region 140 may comprise a trench in the substrate 101, and it is preferable that a plurality of refractive index adjustment regions 140 are spaced apart from each other between the adjacent DTI structures 130. In addition, it is preferable that the refractive index adjustment region 140 have a smaller depth than the DTI structures 130 in the substrate 101. The refractive index adjustment region 140 may include the second boundary region 141 and the second center structure 143.

The second boundary region 141 comprises an insulation film along the boundary of the individual refractive index adjustment region 140. As described above, the second boundary region 141 may be connected to the first boundary region 131 by the first connection region 151. In addition, when a plurality of second boundary regions 141 are in the substrate 101, adjacent second boundary regions 141 may also be connected to each other by the first connection regions 151. It is preferable that the second boundary region 141 comprises the same material as the first connection region 151 and the first boundary region 131, and is formed substantially and simultaneously in the same process(es). In addition, the second boundary region 141 may have substantially the same thickness along the boundary of the individual refractive index adjustment region 140, but there is no specific limitation.

The second center structure 143 is a part of the refractive index adjustment region 140, together with the second boundary region 141, and may fill and/or be on the second boundary region 141. In addition, the second connection region 143 may be connected to the first center structure 144 by the second connection region 153. In addition, when a plurality of refractive index adjustment regions 140 are between the adjacent DTI structures 130, the second center structure(s) 143 of the adjacent refractive index adjustment regions 140 may be connected to each other by the second connection region 153. It is preferable that the second center structure 143 comprises the same material as the second connection region 153 and the first center structure 133, and is formed substantially and simultaneously in the same process(es).

The first connection region 151 is between the refractive index adjustment region 140 and the adjacent DTI structures 130 on the back surface 1013 of the substrate 101 and between the adjacent refractive index adjustment regions 140, and preferably comprises an insulating material. For example, the first connection region 151 is on the back surface 1013 of the substrate 101, and is between the adjacent DTI structures 130 and the refractive index adjusting region 140. Furthermore, the first connection region 151 may connect adjacent refractive index adjustment regions 140 to each other. In addition, the second connection region 153 may be on the first connection region 151.

The second connection region 153 is a layer on the first connection region 151 or the back surface 1013 of the substrate 101, and it is preferable that the second connection region 153 is on the DTI structures 130, the refractive index adjustment region 140, and the first connection region 151. For example, the second connection region 153 may cover all areas of the individual unit pixels P1, but there is no specific limitation. By such a structure, the second connection region 153 may be on the first connection region 151 and connected to uppermost surfaces of the first center structures 133 and the second center structures 143.

A first interlayer insulation film 160 may be on the second connection region 153. The first interlayer insulation film 160 may comprise an oxide film as described herein, for example, and may be continuous on the second connection region 153.

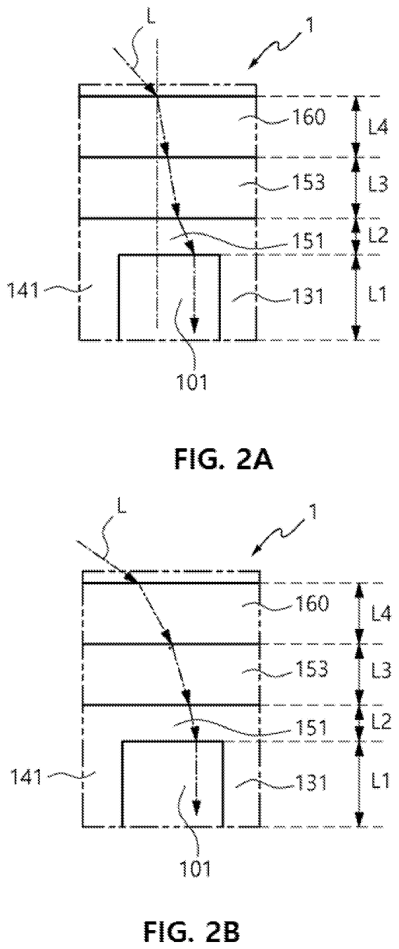

FIGS. 2A and 2B are reference views comparing light paths through the backside illuminated image sensor of FIG. 1.

By a structure described above, referring to FIGS. 1 to 2B, the adjacent refractive index adjustment regions 140 in the unit pixels P1 and/or the DTI structures 130 adjacent to the refractive index adjustment regions 140 may comprise four layers.

In describing the present disclosure in detail with reference to FIGS. 2A and 2B, the substrate 101 may include a first layer L1 including the first boundary region 131 and the second boundary region 141, a second layer L2 including the first connection region 151, a third layer L3 including the second connection region 153, and a fourth layer L4 including the first interlayer insulation film 160. The first layer L1 has a first refractive index n1, the second layer L2 has a second refractive index n2, the third layer L3 has a third refractive index n3, and the fourth layer L4 has a fourth refractive index n4.

The first refractive index n1 to the fourth refractive index n4 that are described above satisfy equation (1) below (see FIG. 2A):

n1>n3>n2>n4 (1)

n1>n2>n3>n4 (2)

In contrast, when equation (2) is satisfied, light L may converge to the light receiving element 110 as the light L passes through the first layer L1 from the fourth layer L4, and the light L passes through the substrate 101 at an angle close to vertical. However, in the near infrared wavelength band, the path of the corresponding light L decreases and sensitivity decreases, and a sensitivity-increasing effect using a scattering pattern of the refractive index adjustment region 140 may be inefficient (see FIG. 2B).

Therefore, by configuring the image sensor 1 of the present disclosure to satisfy the equation (1), incident light L is refracted along a horizontal direction in the second layer L2 (see FIG. 2A), rather than in the depth direction of the substrate 101 (see FIG. 2B), thereby increasing the distance of the light path and increasing the photoelectric effect in the light receiving element 110, so that sensitivity may increase in the near infrared band.

In describing the present disclosure again with reference to FIG. 1, a second interlayer insulation film 170 may be on the first interlayer insulation film 160. A light shield 171 may be in the second interlayer insulation film 170 (e.g., on the first interlayer insulation film 160 and covered by the second interlayer insulation film 170), at a boundary between adjacent unit pixels P1. The light shield 171 comprises a metal such as tungsten (W) or aluminum as an example, and is configured to prevent light that passes through a color filter 180 from crossing over to the adjacent pixel P1. That is, the light shield 171 is configured to prevent cross-talk between the adjacent pixels P1.

The color filter 180 may be on the second interlayer insulation film 170. The color filter 180 is configured to select a color of light (for example, red light, green light, or blue light) from the lens 190 to pass through to the light receiving element 110 of the corresponding unit pixel P1.

In addition, a planarization layer 181 may be on the color filter 180. The planarization layer 181 may comprise a silicon oxide film as an example.

The lenses 190 are on the planarization layer 181, and the lenses 190 may comprise a plurality of micro lenses on the color filter 180 configured to focus light from the back surface 1013 of the substrate 101 to the light receiving element 110 in the unit pixel P1. The planarization layer 181 and the color filter 180 are on the second interlayer insulation film 170, and may connect the color filter 180 and the second interlayer insulation film 170 together.

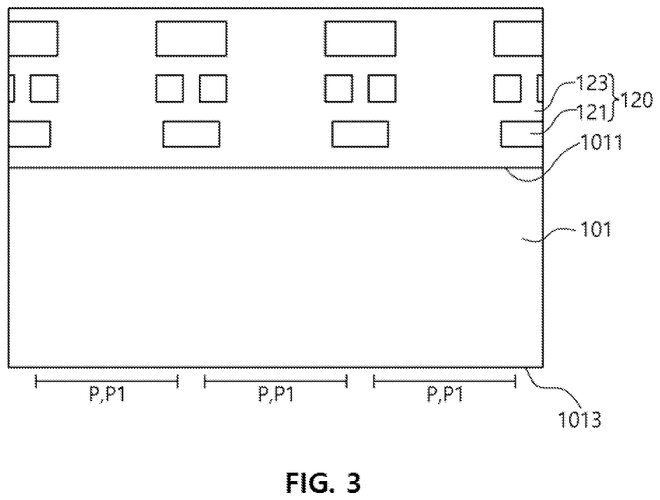

FIGS. 3 to 8 are cross-sectional views illustrating structures made during a method manufacturing of the backside illuminated image sensor according to one or more embodiments of the present disclosure.

Hereinafter, a method of manufacturing a backside illuminated image sensor according to one or more embodiments of the present disclosure will be described in detail with reference to the accompanying drawings.

First, referring to FIG. 3, the wiring region 120 is conventionally formed on the front surface 1011 of the substrate 101 including an STI region (not illustrated, and which may define an active region of the unit pixel P). As described above, the wiring region 120 includes the metal wiring layer 121 and the lower insulation film 123, and the lower insulation film 123 and the metal wiring layer 121 may be alternately formed on the front surface 1011 of the substrate 101, and the detailed description thereof will be omitted.

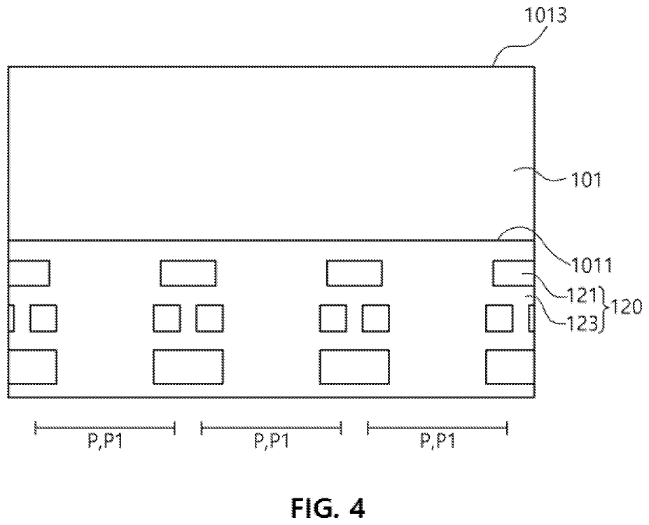

Then, referring to FIG. 4, the substrate 101 is thinned (e.g., by grinding or polishing the back surface 1013 of the substrate 101, opposite from the wiring region 120).

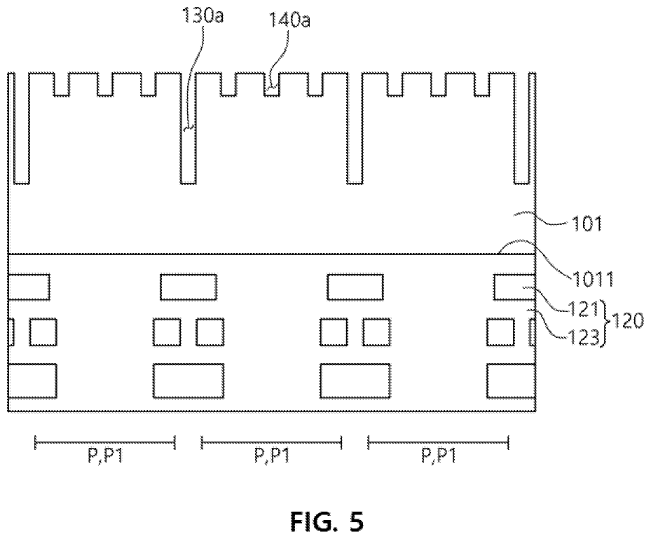

Then, referring to FIG. 5, first trenches 130a having a first predetermined depth within the substrate 101 from the back surface 1013 are formed by etching areas of the substrate 101 exposed by a conventionally-formed first photoresist pattern (not illustrated), utilized as a first mask. Then, second trenches 140a having a second, smaller predetermined depth within the substrate 101 from the back surface 1013 are formed by etching areas of the substrate 101 exposed by a conventionally-formed second photoresist pattern (not illustrated), utilized as a second mask. The second trenches 140a are shallower than the first trenches 130a, and may be formed by an etching process similar to that forming the first trenches 130a.

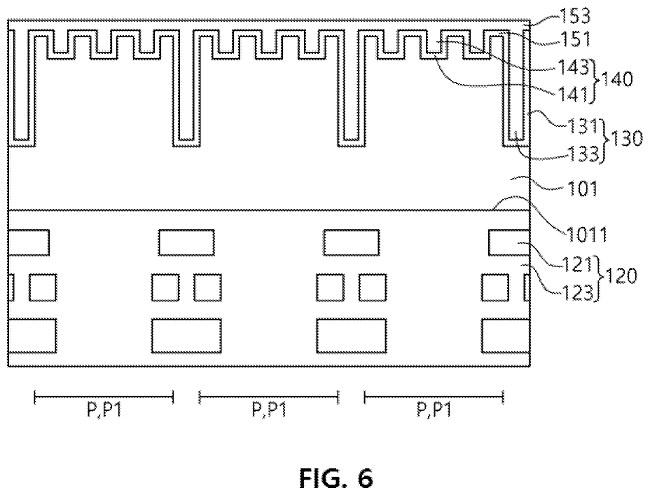

Then, referring to FIG. 6, a first insulating material may be conformally deposited in the first trenches 130a, the second trenches 140a, and on the back surface 1013 of the substrate 101 to form the first boundary region 131, the second boundary region 141, and the first connection region 151. Alternatively, when the substrate 101 comprises a silicon wafer or epitaxial silicon on a silicon wafer, the first insulating material may be formed by wet or dry thermal oxidation of the silicon.

Then, a second insulating material is deposited on the first insulating material in the first trench 130a and the second trench 140a and on the first connection region 151 to form the first center structure 133, the second center structure 143, and the second connection region 153. The second insulating material is then planarized (e.g., by CMP) to provide the planar uppermost surface of the second connection region 153.

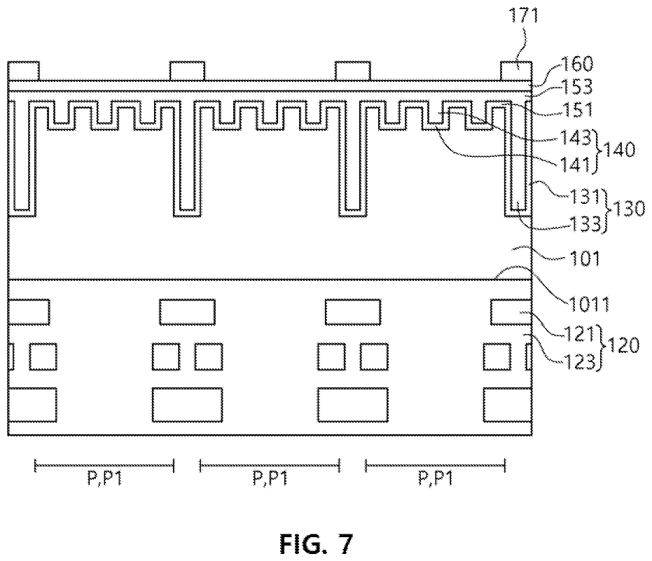

As a subsequent process, referring to FIG. 7, the first interlayer insulation film 160 is conventionally formed (e.g., by blanket or conformal deposition) on the second connection region 153. Then, the light shield 171 is formed on the first interlayer insulation film 160. After a blanket metal film (not illustrated) is deposited (e.g., by sputtering or chemical vapor deposition [CVD]) on the first interlayer insulation film 160, the light shield 171 may be formed by etching exposed areas of the blanket metal film using a photoresist pattern (not illustrated) as a mask.

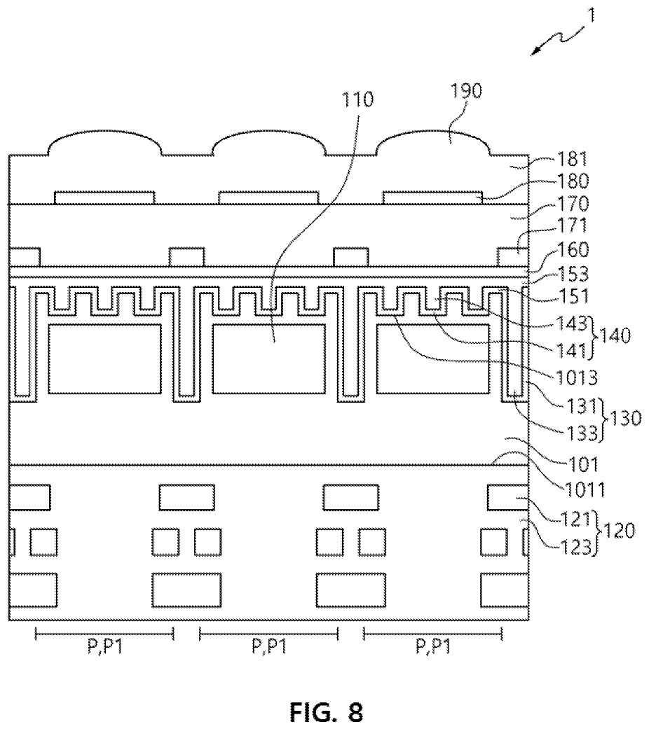

Then, referring to FIG. 8, the second interlayer insulation film 170 is conventionally formed on the first interlayer insulation film 160 to cover the light shield 171. The second insulating interlayer insulation film 170 may be planarized (e.g., by CMP) to provide the planar uppermost surface thereof. In addition, the color filter 180 is conventionally formed on the second interlayer insulation film 170, and the planarization layer 181 and the lens 190 are formed conventionally, in sequence

The foregoing detailed description is for illustrative purposes only. Further, the description provides embodiments of the present disclosure, and the present disclosure may be used in other various combination, changes, and environments. That is, the present disclosure may be changed or modified within the scope of the present disclosure described herein, a range equivalent to the description, and/or within the knowledge or technology in the related art. The embodiments may show an optimum state for achieving the spirit of the present disclosure, and various modifications for specific applications and/or uses of the present disclosure are also possible. Therefore, the detailed description of the present disclosure is not intended to be limited to the disclosed embodiments.

What is claimed is:

1. A backside illuminated image sensor comprising:
a substrate having a front surface and a back surface;
a light receiving element in the substrate;
a plurality of deep trench isolation (DTI) structures at boundaries between adjacent unit pixels in the substrate, the DTI structures having a first depth; and
a refractive index adjustment region having a second depth less than the first depth, and being between adjacent DTI structures in the substrate,
wherein each of the DTI structures comprises:
a first boundary region at a boundary of each of the DTI structures and comprising a first material; and
a first center structure on the first boundary region and comprising a second material different from the first material, and
the refractive index adjustment region comprises:
a second boundary region at a boundary of the refractive index adjustment region and comprising a third material; and
a second center structure on the second boundary region and comprising a fourth material different from the third material.

2. The backside illuminated image sensor of claim 1, wherein the first boundary region comprises a same material as the second boundary region, and the first center structure comprises a same material as the second center structure.

3. The backside illuminated image sensor of claim 2, further comprising:
a first connection region connecting each of the DTI structures and the refractive index adjustment region, or connecting the adjacent DTI structures to each other; and
a second connection region on the first connection region, the second connection region connecting the first center structure and the second center structure to each other.

4. The backside illuminated image sensor of claim 3, wherein the first connection region comprises a same material as the first boundary region, and the second connection region comprises a same material as the first center structure.

5. The backside illuminated image sensor of claim 4, wherein the substrate has a first refractive index, the first connection region has a second refractive index smaller than the first refractive index, and the second connection region has a third refractive index larger than the second refractive index.

6. The backside illuminated image sensor of claim 5, further comprising a first interlayer insulation film on the second connection region,
wherein the first interlayer insulation film has a fourth refractive index smaller than the second refractive index.

7. A backside illuminated image sensor comprising:
a substrate having a front surface and a back surface;
a light receiving element in the substrate;
a plurality of DTI structures at boundaries between a plurality of unit pixels;
a refractive index adjustment region between adjacent DTI structures in the substrate; and
a first interlayer insulation film on a second connection region,
wherein each of the DTI structures comprises:
a first boundary region at a boundary of each of the DTI structures and comprising a first material; and
a first center structure being on the first boundary region and comprising a second material different from the first material, and
the refractive index adjustment region comprises:
a second boundary region at a boundary of the refractive index adjustment region and comprising a third material; and
a second center structure being on the second boundary region and comprising a fourth material different from the third material.

8. The backside illuminated image sensor of claim 7, further comprising:
a first connection region connecting each of the DTI structures and the refractive index adjustment region;
a second connection region connecting the first center structure and the second center structure;
a first layer in the substrate, having a first refractive index and including the first boundary region and the second boundary region;
a second layer on the first layer, having a second refractive index and including the first connection region;
a third layer on the second layer, having a third refractive index and including the second connection region is formed; and
a fourth layer on the third layer, having a fourth refractive index and including the first interlayer insulation film is formed,
wherein the first refractive index is larger than the third refractive index, and the second refractive index is smaller than the first and third refractive indexes and which larger than the fourth refractive index.

9. The backside illuminated image sensor of claim 8, wherein the refractive index adjustment region has a depth shallower than a depth of each of the DTI structures in the substrate.

10. The backside illuminated image sensor of claim 8, further comprising:
a second interlayer insulation film on the first interlayer insulation film;
a light shield at the boundary of each of the unit pixels and in the second interlayer insulation film;
a color filter on the second interlayer insulation film; and
a lens on the color filter.

11. The backside illuminated image sensor of claim 8, wherein the refractive index adjustment region comprises a plurality of refractive index adjustment regions, and the plurality of refractive index adjustment regions are spaced apart from each other between adjacent ones of the DTI structures in each of the unit pixels.

12. The backside illuminated image sensor of claim 8, wherein the first boundary region is formed substantially simultaneously with the second boundary region and the first connection region, and the first center structure is formed substantially simultaneously with the second center portion and the second connection region.

13. The backside illuminated image sensor of claim 8, wherein the first boundary region comprises a first insulating material having a fifth refractive index, the first center structure comprises a second insulating material having a sixth refractive index, and the fifth refractive index is smaller than the sixth refractive index.

14. A backside illuminated image sensor comprising:
a substrate having a front surface and a back surface;
a first layer having a first refractive index and comprising a plurality of trench structures in the substrate and spaced apart from each other;
a second layer having a second refractive index and comprising a plurality of connection structures on the first layer, connecting adjacent trench structures;
a third layer having a third refractive index, on the second layer and covering the trenches and connection structures; and
a fourth layer having a fourth refractive index and comprising an interlayer insulation film structure on the third layer,
wherein the first refractive index is larger than the third refractive index, and the second refractive index is smaller than the first and third refractive indexes and larger than the fourth refractive index.

15. The backside illuminated image sensor of claim 14, further comprising:
an insulation film on the fourth layer; and
a light shield comprising a metal film at a boundary of a unit pixel and in the insulation film.

16. The backside illuminated image sensor of claim 15, further comprising:
a color filter on the insulation film;
a planarization layer on the color filter; and
a lens on the planarization layer.

17. The backside illuminated image sensor of claim 16, further comprising a wiring region on the front surface of the substrate.

18. A method of manufacturing a backside illuminated image sensor, the method comprising:
forming a wiring region on a front surface of a substrate;
forming first trenches in a back surface of the substrate;
forming a second trench between the first trenches, the second trench having a depth less than that of the first trenches;
forming a first insulating material having a first refractive index in the first trenches, in the second trench, and on the back surface of the substrate;
forming a second insulating material on the first insulating material, the second insulating material having a second refractive index which is larger than the first refractive index and smaller than a third refractive index of the substrate; and
forming an interlayer insulation film on the second insulating material, the interlayer insulation film having a fourth refractive index smaller than the first refractive index.

19. The method of claim 18, wherein the second trench comprises a plurality of second trenches, and the plurality of second trenches are between the adjacent first trenches.
